(19) United States
(12) Patent Application Publication
(10) Pub. No.: US 2014/0202837 A1
(43) Pub. Date: Jul. 24, 2014

(54) LOW-COST PROCESS-INDEPENDENT RF MEMS SWITCH

(71) Applicant: Purdue Research Foundation, West Lafayette, IN (US)

(72) Inventors: Adam Joseph Fruehling, West Lafayette, IN (US); Dimitrios Peroulis, West Lafayette, IN (US)

(73) Assignee: Purdue Research Foundation, West Lafayette, IN (US)

(21) Appl. No.: 14/019,939

(22) Filed: Sep. 6, 2013

Related U.S. Application Data
(63) Continuation-in-part of application No. 13/404,880, filed on Feb. 24, 2012, now abandoned.
Application No. 13/404,880 is a continuation of application No. 12/808,002, filed on Jun. 14, 2010, now abandoned.

(51) Int. Cl. H01H 59/00; B81C 1/00

(52) U.S. Cl. CPC H01H 59/0009; B81C 1/0015; B81C 1/00166
USPC 200/181; 438/619

(57) ABSTRACT

A MEMS switch includes a semiconductor substrate, a movable cantilever and a cantilever anchor. The semiconductor substrate includes a device layer and a handle. The movable cantilever is formed in the semiconductor substrate, and is disposed over a void in the handle. The cantilever anchor is formed in the semiconductor substrate and defines a side wall of the void. A metal portion is formed on at least a portion of the movable cantilever. A metal contact is formed proximate an end of the movable cantilever. A biasing metal contact is formed adjacent the cantilever. The biasing metal contact is electrically disconnected from the metal contact.

This application is a continuation-in-part of application Ser. No. 13/404,880, filed Feb. 24, 2012, which is a continuation of application Ser. No. 12/808,002, filed Jun. 14, 2010, which is the U.S. National Stage of International Application No. PCT/US08/86897, filed Dec. 15, 2008, which claims the benefit of Provisional Patent Application No. 61/013,537, filed Dec. 13, 2007, which applications are hereby incorporated by reference along with patent application Ser. No. 11/963,071, filed Dec. 21, 2007.

### BACKGROUND OF THE INVENTION

This invention relates to micro-electromechanical systems (MEMS) and, more particularly, MEMS switches.

Radio frequency MEMS technology has been under development for nearly two decades now. In this technology, integrated circuits are fabricated with miniaturized mechanical moving parts (e.g., beams and plates) that can be actuated in a variety of ways including electrostatically, magnetically, electrothermally, piezoelectrically and others. The induced mechanical movement reconfigures the electrical circuitry and thus provides additional functionality. Typical devices produced by this methodology include RF switches and variable capacitors that can be applied to reconfigurable filters, antennas, and matching networks to name a few examples. RF MEMS switches are dominant devices in this technology because they provide the maximum possible adaptability. While reconfigurability can also be achieved with solid-state switches (diodes and transistors), RF MEMS switches offer many significant advantages including low loss, ultra-low power consumption, high isolation, and ultra-high linearity.

Unlike conventional MEMS inertia sensors (accelerometers and gyroscopes), which have now become commercially available, RF MEMS switches face significant challenges to enter the commercial world. They only began to be commercially available in about 2005. Conventional solid-state switches have inferior performance, but they are generally cheaper, and the pricing makes the conventional solid-state switches more attractive than the RF MEMS switches. This difference in price is not explained by the inherent cost of the manufacturing processes, since they are similar. The price difference is attributed to low manufacturing yield of RF MEMS switches.

This low manufacturing yield is largely due to a single factor: high process variability. Unlike the CMOS industry that uses dedicated tools tuned for only one function, the production paradigm is very different for the RF MEMS industry. The RF MEMS industry is significantly smaller in volume and therefore cannot afford to have dedicated foundries and processes for each process and each device. Instead, most RF MEMS companies utilize general foundries, of which there are approximately 25 around the world. These foundries use the same tools to fabricate products for their various customer. These products can vary widely including switches, optical mirrors, infrared sensors and bio-sensors. However, high-yield manufacturing requires a different assembly line for each product with well-characterized and well-tuned tools that only produce that particular product without being contaminated with foreign films and processes. This is not possible for many of these devices because of their low commercial volume. Consequently, they need to be manufactured with common tools that suffer from great process variations.

There exists a need for a MEMS switch, and particularly an RF MEMS switch, that exhibits more repeatable electrical and mechanical performance than heretofore possible. A related need exists for an RF MEMS switch that can be cost-effectively produced with very high yield.

### SUMMARY OF THE INVENTION

The present invention provides a MEMS switch comprising a stationary portion having a first electrical contact and a monocrystalline movable portion having a second electrical contact on an end thereof. The monocrystalline movable portion is operatively positioned relative to the stationary portion such that the first electrical contact is connected to the second electrical contact in a closed state of the MEMS switch and disconnected from the second electrical contact in an open state of the MEMS switch.

Another aspect of the invention is a MEMS switch that includes a semiconductor substrate, a movable cantilever and a cantilever anchor. The semiconductor substrate includes a device layer and a handle. The movable cantilever is formed in the semiconductor substrate, and is disposed over a void in the handle. The cantilever anchor is formed in the semiconductor substrate and defines a side wall of the void. A metal portion is formed on at least a portion of the movable cantilever. A metal contact is formed proximate an end of the movable cantilever. A biasing metal contact is formed adjacent the cantilever. The biasing metal contact is electrically disconnected from the metal contact.

A general object of some embodiments of the present invention is to provide an improved MEMS switch and a process for manufacturing the switch.

A further object of some embodiments is to provide a MEMS switch that can be manufactured with very high yield despite high variability of process parameters. For, example, embodiments of the present invention have properties including one or more of actuation voltage, contact resistance, and residual stress that are essentially independent of the specific fabrication parameters of the foundry producing the device, such that the properties do not vary significantly from die to die, wafer to wafer, lot to lot, or even foundry to foundry.

Another object of some embodiments is to provide a MEMS switch that can readily be fabricated using ordinary CMOS techniques.

Other objects and advantages of the present invention will be more apparent upon reading the following detailed description in conjunction with the accompanying drawings.

### BRIEF DESCRIPTION OF THE DRAWINGS

FIG. 1 illustrates a MEMS switch.

FIG. 2 shows a measured and calculated pull-in voltages for SOI cantilevers.

FIG. 3 illustrates a sample fabrication process for SOI MEMS device.

FIG. 4 shows a measured on state performance.

FIG. 5 shows a measured off state performance.

FIG. 6 shows a measured on switching speed.

FIG. 7 shows a measured off switching speed.

FIG. 8 illustrates a diagram of a monocrystalline MEMS switch.

FIG. 9 shows a SE overview of a switched CPW line with a SEM inset detail of a switch contact.

FIG. 10 shows a SEM view of a MEMS switch contact.

FIG. 11 shows a magnified image of patterned beam with contact metal deposited and patterned corresponding to FIG. 3-B in the fabrication process.

FIG. 12 shows a magnified image of patterned beam with contact and patterned sacrificial layer corresponding to FIG. 3-C in the fabrication process.

FIG. 13 shows a magnified image of patterned lines suspended above unreleased switches corresponding to FIG. 3-D in the fabrication process.

FIG. 14 shows a magnified overview image of completed switch structure corresponding to FIG. 3-D in the fabrication process.

FIG. 15 shows a magnified image of patterned and released beam without previous layers deposited corresponding to FIG. 3-F in the fabrication process.

FIG. 16 illustrates a top view of an HFSS drawing of a switch structure.

FIG. 17 illustrates a three-dimensional view of a MEMS switch.

FIG. 18 illustrates the long term bias stability versus time for different cantilever materials in air.

FIG. 19 illustrates a full-wave simulation of switch on-state return loss.

FIG. 20 illustrates a full-wave simulation of switch on-state insertion loss

FIG. 21 shows an HFSS simulation plot of return loss from 1 mm switched CPW on SOI.

FIG. 22 shows an HFSS simulation plot of insertion loss from 1 mm switched CPW on SOI.

FIG. 23 illustrates a DC ohmic contact switch.

FIG. 24 shows a SEM of DC ohmic contact switch.

FIGS. 25A-25E show an alternative embodiment of an RF switch;

FIGS. 26A-26G show cutaway side views of the RF switch of FIGS. 25A-25E at different stages of fabrication;

FIGS. 27A-26G show top plan views of the RF switch of FIGS. 25A-25E at different stages of fabrication;

FIGS. 28E-28G show cutaway views of the RF switch of FIGS. 25A-25E at different stages of fabrication;

FIGS. 29A-29E show yet an alternative embodiment of an RF switch;

FIGS. 30A-30C show top plan views of the RF switch of FIGS. 29A-29E at different stages of fabrication;

FIGS. 31A-31C show cutaway views of the RF switch of FIGS. 29A-29E at different stages of fabrication;

FIG. 32 shows a perspective view of yet another RF MEMS switch.

### DETAILED DESCRIPTION OF PREFERRED EMBODIMENTS

For the purpose of promoting an understanding of the principles of the invention, reference will now be made to the embodiments illustrated in the drawings and specific language will be used to describe the same. It will nevertheless be understood that no limitation of the scope of the invention is thereby intended, such alterations and further modifications in the illustrated device and such further applications of the principles of the invention as illustrated therein being contemplated as would normally occur to one skilled in the art to which the invention relates.

The present invention provides a new MEMS switch design that is substantially independent of most or all of the aforementioned process variability. This MEMS switch preferably has a moving part made of undoped monocrystalline silicon. Its monocrystalline nature renders this material among the purest available with significant fewer defects than any other material available in the integrated circuit industry. In addition, undoped monocrystalline silicon has insignificant variability in its material properties, allowing the MEMS designer to know them a priori. The moving part can also be made of other monocrystalline materials and may be in the form of a cantilever beam, fixed-fixed beam, a plate, or a combination. The nonmoving part also has the same variations depending on the moving part.

The fabrication process of the RF MEMS switch is also compatible with CMOS electronics fabricated on Silicon-on-Insulator (SOI) substrates. Both the RF circuitry and the switch actuators are fabricated on a single SOI substrate.

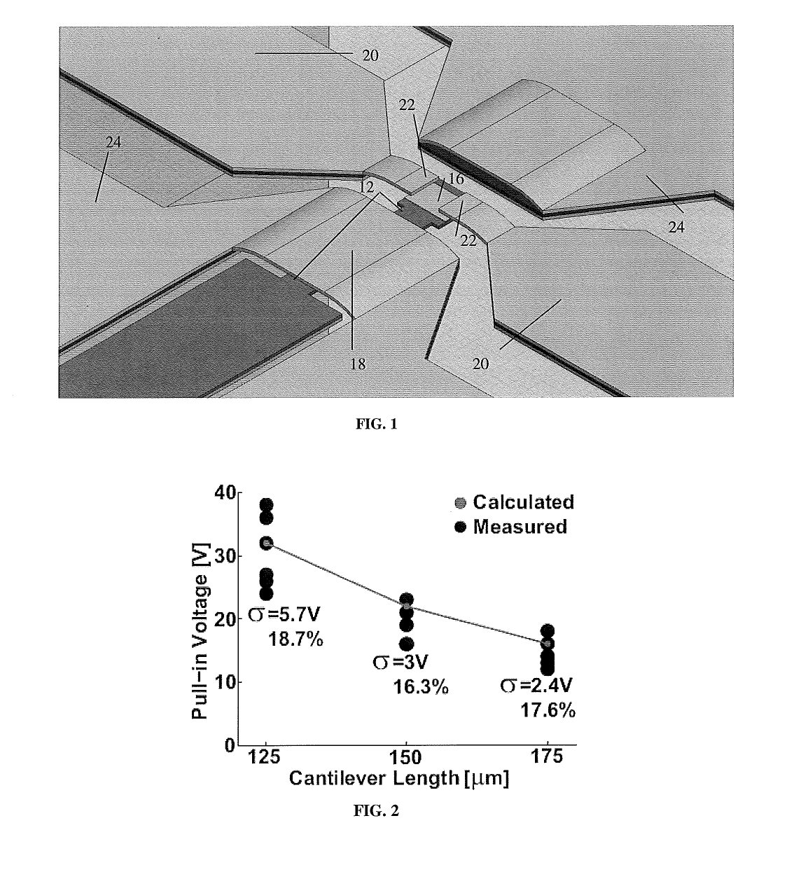

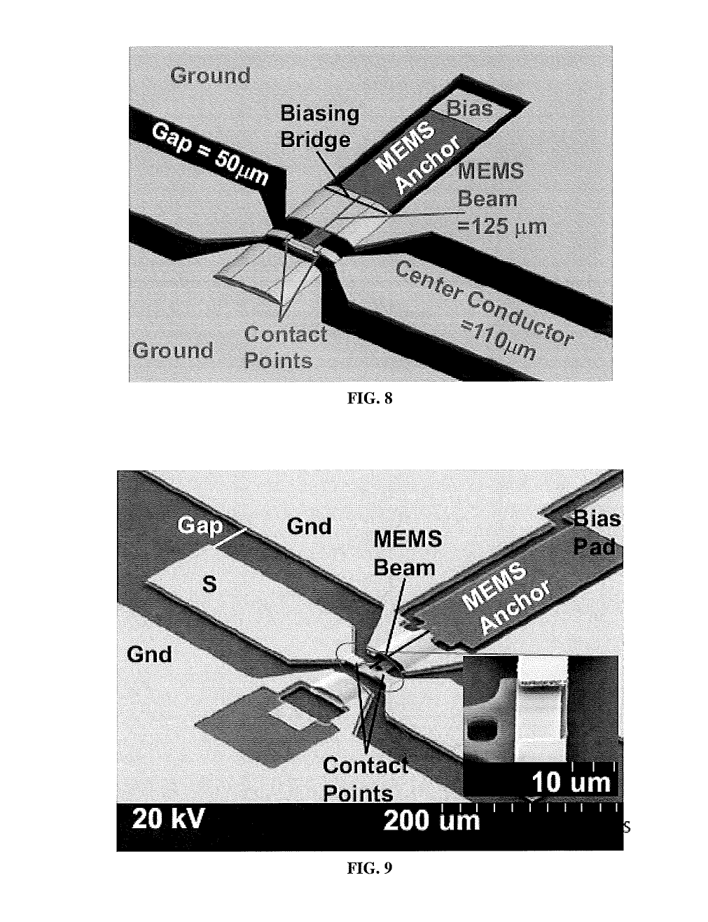

FIG. 1 illustrates a switch according to a first embodiment of the present invention. The disclosed embodiment contains a 2-μm thick single-crystal silicon cantilever beam 12, a 2-μm thick discontinuous gold coplanar waveguide (CPW) line 20 and a 2-μm thick gold biasing electrode illustrated in FIG. 8. The ground planes 24 of the CPW are separated from center line conductor 20 by a gap distance of about 50 μm. The gap distance narrows to 20 μm at the switch. The contact areas 22 of the discontinuous CPW line 20 are suspended approximately 2.5 μm above the silicon cantilever beam 12. The switch is normally fabricated open (off state). The center conductor of the CPW line 20 is discontinuous in this state and the switch offers a high isolation. The silicon beam is coated with a 0.5 μm gold film 16 at the contact area. While this particular implementation utilizes gold-to-gold contacts, other contact materials can readily be used to form the signal line, bias, and contact portions without affecting the structural integrity of the switch. Other metals such as aluminum, copper, and the like are suitable.

When a voltage is applied between the biasing electrode and the silicon beam 12, the beam deflects upward making contact with the contact portion 22 of the discontinuous CPW line 20. When the beam is deflected the gold foil 16 provides a conductive bridge between the discontinuous CPW line 20 segments and the switch is closed (on state).

The pull-in voltage (V_{PI}) required to deflect the beam in the MEMS switch can be determined with the equation

$${V}_{P I} = \sqrt{\frac{8 {k}_{Beam} {g}^{3}}{27 {ε}_{0} A}}$$

where A is the actuation area, g is the gap between the beam and biasing structure in the neutral position, ∈₀ is the permittivity constant of free space, and k_{Beam} is the spring constant of the beam. Assuming a nearly uniform electrostatic force on the cantilever beam, the spring constant (k_{Beam}) is determined with equation

$${k}_{Beam} = \frac{2 E w}{3} {( \frac{t}{l} )}^{3}$$

where E is Young's modulus of the material, w is the width, t is the thickness, l is the length of the beam.

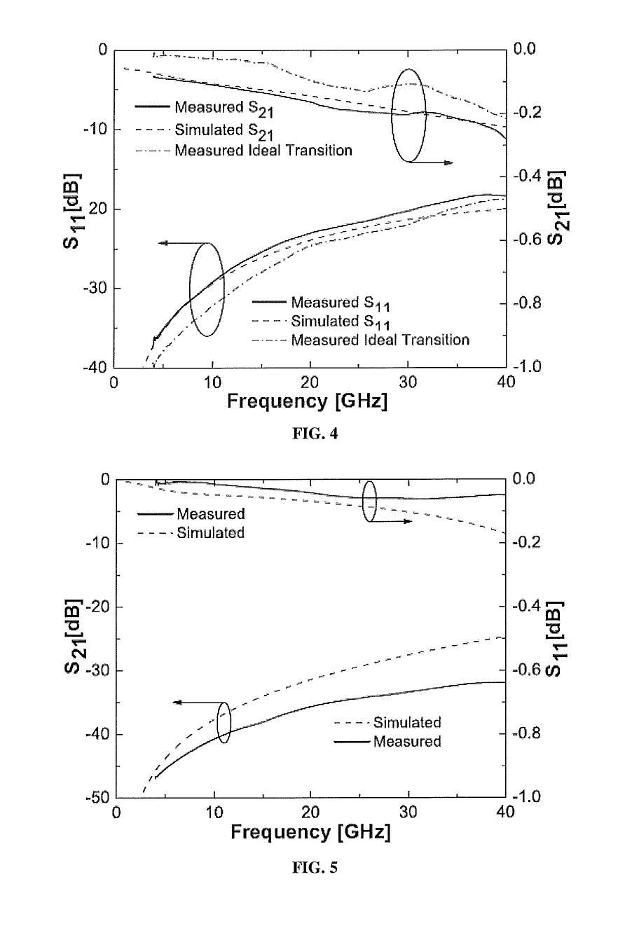

FIG. 2 shows the calculated pull-in voltage as a function of the cantilever length where the width and thickness of the cantilever beam are 20 μm and 2 μm, respectively. FIG. 4 also shows the measured pull-in voltages for these devices. Five theoretically identical beams are measured for beam lengths of 125 μm, 150 μm, and 175 μm. The mean pull-in voltage values and standard deviations for the cantilevers of lengths of 125 μm, 150 μm, and 175 μm are (30.5 V, 18.7%), (18.5 V, 16.3%) and (13.3 V, 17.6%) respectively. These deviations can attributed to thickness variations of just 0.25 μm from the center to the edge of the wafer. This variation is prescribed by the wafer's manufacturer due to uneven polishing of the SOI device layer.

The pull-in voltage variation can be significantly reduced by more careful polishing in a production environment and by using CMOS-grade SOI wafers. As shown in FIG. 1, the biasing structure 18 is stiffer than the beam 12 and has a typical beam to biasing spring constant ratio of 1:50. The metal structures of the biasing structure are deposited with tensile stress, and any variation in stress of the deposited film during fabrication serves only to stiffen the biasing structure as can be seen in the biasing structure spring constant (k_{Biasing}) equation

$${k}_{Biasing} = 32 {Ew ( \frac{t}{l} )}^{3} + 8 σ ( 1 - v ) w ( \frac{t}{l} )$$

where, σ is the residual stress, and v is the Poisson ratio of the material.

The restoring force and the contact force will vary depending on the application and design of the MEMS switch. The restoring force (Fᵣ) is determined with the equation

Fᵣ=k(g−gₒₙ)

and contact force (F_{c}) is determined with the equation

$${F}_{c} = {ε}_{0} {A ( \frac{{V}_{Actuation}}{2 {g}_{on}} )}^{2}$$

where V_{Actuation} is the applied switch bias, and gₒₙ is the separation between the MEMS device and the biasing pad in the on state. The applied switch bias V_{Actuation} may be higher than the pull-in voltage V_{PI} to achieve the desired contact force value. The secrificial layer thickness and the operating voltage can be varied as needed for the desired restoring force and the contact force of the specific application.

The mechanical design parameters for an embodiment of this application are summarized in Table I. The suspended CPW cantilevers that extend over the end of the switch are approximately, 25 μm×15 μm×2 μm (L×W×T) to ensure a rigid structure for high contact force and to minimize the effects of any fabrication stresses that might tend to curl the beam.

TABLE I
SWITCH PARAMETERS

| Parameter | Value |
|---|---|
| Length [μm] | 65, 125 |
| Width [μm] | 20 |
| Thickness [μm] | 2 |
| k_{Beam} [N/m] | 50, 7 |
| V_{P1} [V] | 117, 32 |
| Switching Speed (ON) [μs] - fastest | 3.6 |
| Switching Speed (OFF) [ns] - fastest | 600 |
| Contact Force [μN] | 125, 18 |
| Restoring Force [μN] | 111, 16 |

An embodiment of MEMS switch has a SOI device layer resistivity of 3-5 Ω-cm and handle layer resistivity of 2 kΩ-cm. This compromise in RF losses is necessary in order to minimize charging phenomena on the SOI layer. Significant charging was observed when high-resistivity SOI beams were employed. The RF performance penalty by the low-resistivity SOI layer is minimized by etching the device and oxide layers except for anchoring of the metal lines. The CPW transition length, where the center conductor of the CPW narrows, and separation width between discontinuous CPW center conductor segments can be minimized to reduce losses and loading due to the switch. The dimensions of an embodiment of a 50-Ω switched CPW are summarized in Table II.

TABLE II
RF DESIGN DIMENSIONS

| Parameter | Value |
|---|---|
| CPW center conductor [μm] | 110 |
| CPW gap [μm] | 50 |
| Transition Length [μm] | 50 |
| CPW center conductor at switch [μm] | 15 |
| CPW gap at switch [μm] | 20 |
| Separation between CPW segments [μm] | 25 |
| Separation between CPW and switch [μm] | 2.5 |

The main challenge in using undoped monocrystalline silicon as the structural moving part of a MEMS switch is its very high RF loss. Therefore, careful RF design and fabrication process flow are needed for a successful device.

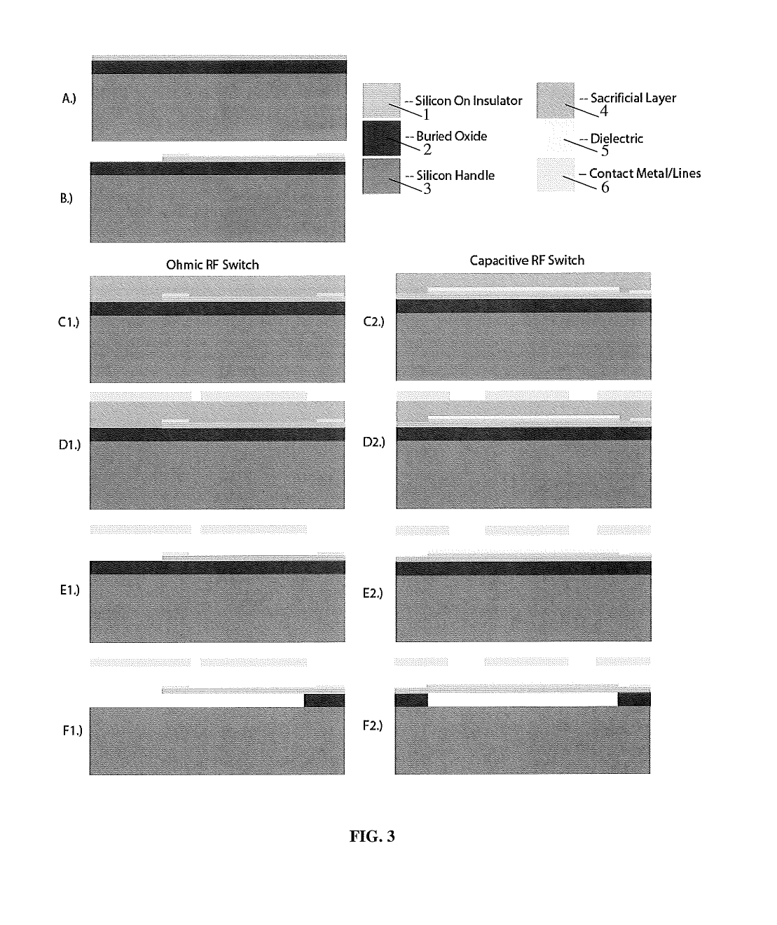

FIG. 3 shows a presently preferred fabrication process. The developed fabrication process has been used to design an RF MEMS switch suitable for operating from DC to 100 GHz. The switch can be fabricated using Silicon-On-Insulator (SOI) CMOS electronics. The fabrication process can yield both metal-to-metal contact switches and metal-to-dielectric contact switches. The metal-to-metal switch is well suited for the 0-60 GHz range, and the metal-to-dielectric switch is well suited to the 10-100 GHz range.

The process begins with a bare SOI wafer having of silicon on insulator 1, a buried oxide layer 2, and a silicon handle 3 as shown in FIG. 3-A.

The wafer is patterned using positive photolithography techniques. The precursor for the movable structure is formed from the silicon on insulator layer 1, also known as the device layer. The device layer beam is patterned and reactive ion etched using SF₆ plasma. KOH may also be used as an etchant to remove a portion of the silicon on insulator layer 1 so that the part that will become the movable portion is shaped. RF contacts lines 6 are deposited and patterned using photolithography and etching as shown in FIG. 3-B.

The fabrication process can vary depending on whether an ohmic or a capacitive switch is fabricated. In the ohmic switch fabrication process, a sacrificial layer 4 is deposited and patterned as shown in FIG. 3-C1. Using positive resist, the sacrificial layer is patterned and baked. The sacrificial layer can be a dielectric layer and provides rigid support for additional layers. The sacrificial layer 4 fills the void created by the removal of a portion of the silicon on insulator layer 1. The sacrificial layer 4 provides a foundation on which a second set of contact metal lines 6 is deposited and provides a physical separation of the second set of contact metal lines 6 from the first set of contact metal lines 6. This step can be repeated multiple times as needed to achieve both a rigid and removable structures.

The second set of contact metal lines 6 comprises the signal line and the biasing pad. The signal line and the biasing structure are deposited on the sacrificial layer as shown in FIG. 3-D1. The signal lines and biasing structure are deposited and anchored to non-beam portions of the device layer silicon or they may be anchored to the buried oxide layer. The signal line may be a CPW, microstrip, stripline, slotline, including the asymmetric versions of each, or other signal lines that conduct RF current.

The sacrificial layer 4 is etched and removed as shown in FIG. 3-E1 to allow the beam to move toward the biasing pad. The sacrificial layer may be removed with a hot positive resist stripper release.

The oxide layer 2 is etched and the cantilever portion of the beam is released as shown in FIG. 3-F1. A hafnium dip to etch the buried oxide layer and to release the beam may be used.

If a capacitive switch is desired, a modified fabrication process is implemented following the process illustrated in 3-B. A capacitive switch contains a dielectric layer 5 and a sacrificial layer 4 as illustrated in FIG. 3-C2. The dielectric 5 is patterned with the movable portion and will remain coupled to the moveable portion. The dielectric and the sacrificial layer are deposited and patterned as described for the process of fabricating the ohmic switch.

The lines and biasing layer are deposited on top of the sacrificial layer and dielectric layer as shown in 3-D2. The lines and biasing structures may be anchored to isolated device layer silicon or to the buried oxide layer.

The sacrificial layer 4 is etched and removed as shown in FIG. 3-E2 to allow the movable portion to move toward the biasing pad. The sacrificial layer may be removed with a hot positive resist stripper release.

The oxide layer 2 is etched and the movable portion released from the oxide substrate as shown in FIG. 3-F2. A hafnium dip to etch the buried oxide layer and to release the beam may be used.

RF measurements of an embodiment of the preferred MEMS switch are performed on an Agilent E8361C with an on-wafer calibration kit using 2.4 mm cables and probes. The switch exhibits the desired insertion loss of less than 0.29 dB up to 40 GHz corresponding to a contact resistance of approximately 0.5Ω per contact with two contacts made in the exemplary switch configuration. The isolation is greater than 30 dB up to 40 GHz. This corresponds to an off-state equivalent capacitance of approximately 1.8 fF by curve fitting.

Simulations indicate that the device is capable of much higher frequency operation, however measurements were limited by the use of 2.4 mm components. Measurement results in the on and off states are shown in FIG. 4 and FIG. 5 respectively. In DC operation, embodiments of the disclosed SOI switches have operated for more than 93 million hot cycles (switch current limited to about 200 μA) in open air maintaining consistent pull-in voltages and contact resistances until end of life. Contact resistances of less than 0.5Ω have been measured for bias voltages less than 1.25 V_{PI}.

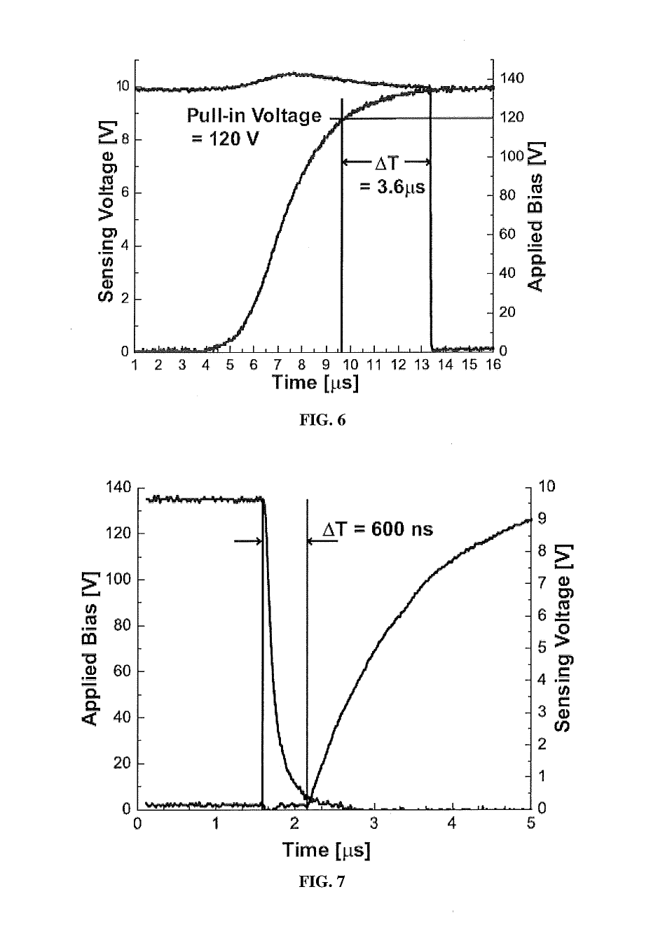

Switching for the shortest devices has been measured at less than 4 μs for the on state, and 600 ns for the off state, as shown in FIG. 6 and FIG. 7, respectively.

FIG. 8 shows a diagram of the monocrystalline MEMS switch. In the illustrated embodiment the center line conductor is 110 μm wide and is separated from the ground plane by a distance of 50 μm, but the gap narrows as the center conductor of the CPW tapers to the contact point.

FIG. 9 shows a SE overview of a switched CPW line with a SEM inset detail of a switch contact.

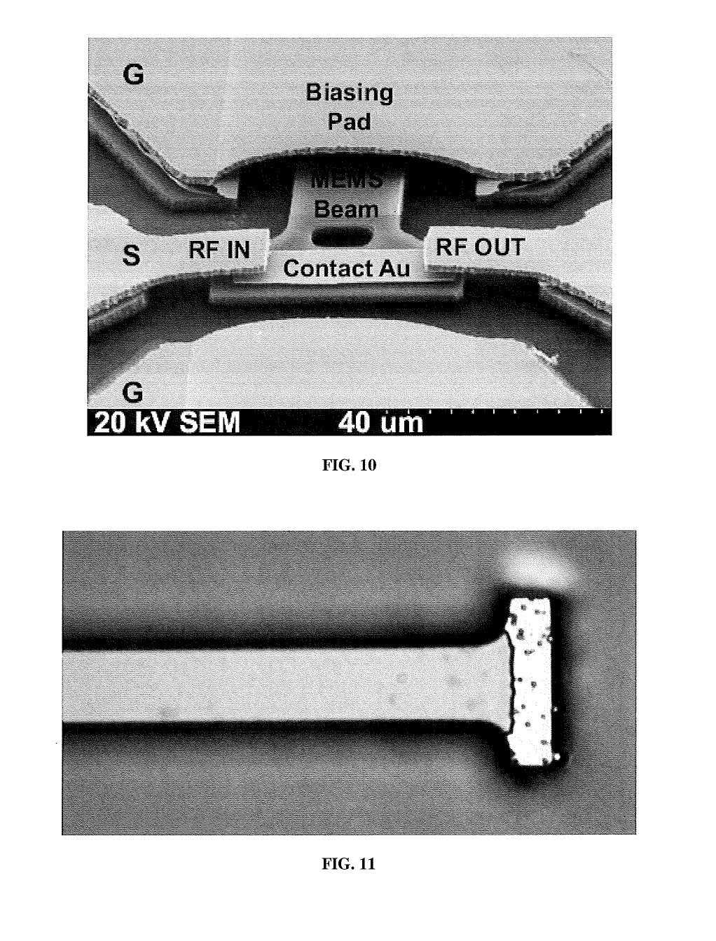

FIG. 10 shows a SEM view of a MEMS switch contact.

FIG. 11 shows a magnified image of patterned beam with contact metal deposited and patterned corresponding to FIG. 3 B in the fabrication process.

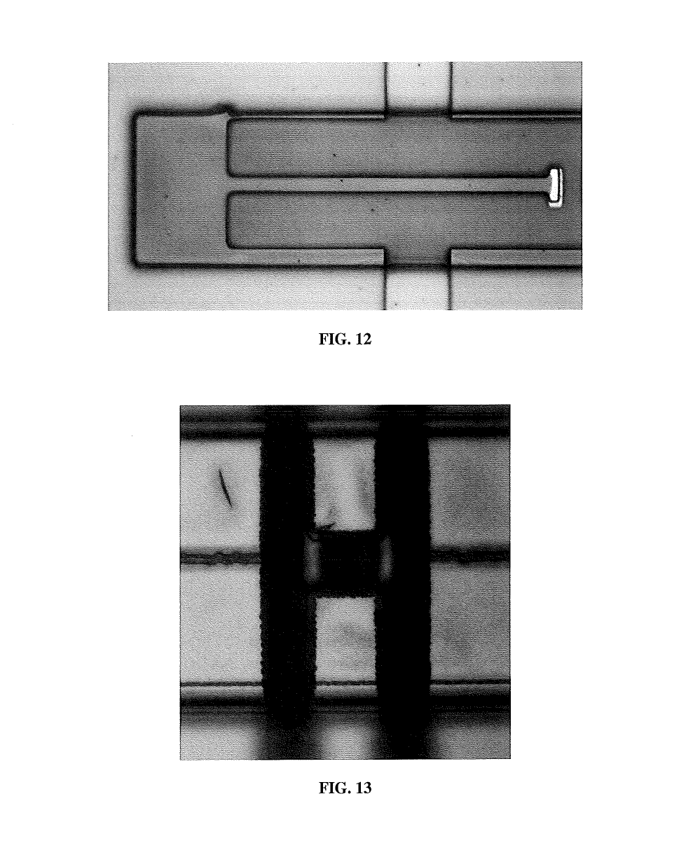

FIG. 12 shows a magnified image of patterned beam with contact and patterned sacrificial layer corresponding to FIG. 3C in the fabrication process.

FIG. 13 shows a magnified image of patterned lines suspended above unreleased switches corresponding to FIG. 3D in the fabrication process.

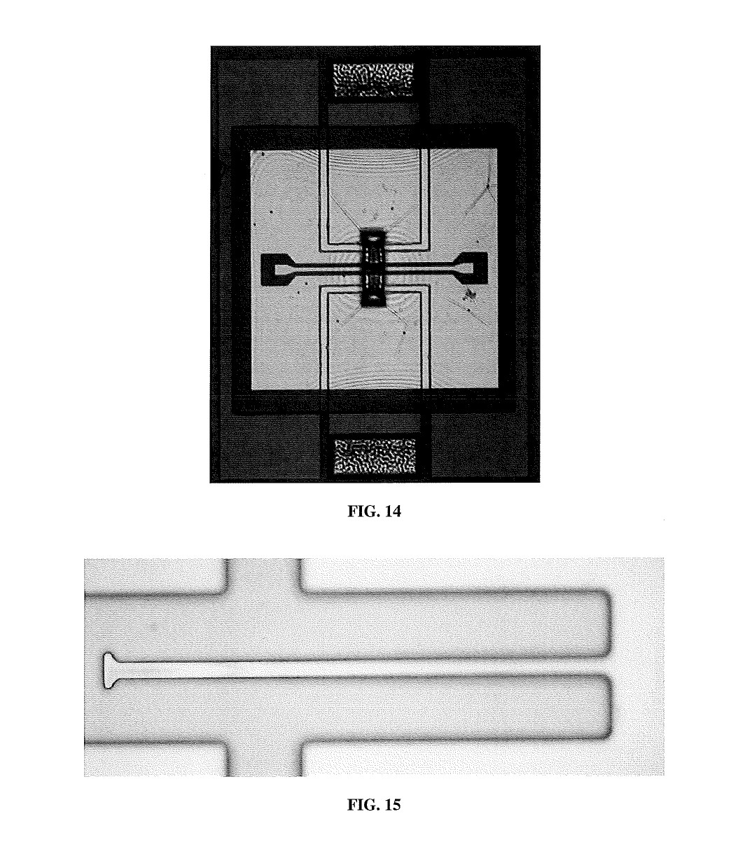

FIG. 14 shows a magnified overview image of completed switch structure corresponding to FIG. 3D in the fabrication process.

FIG. 15 shows a magnified image of patterned and released beam without previous layers deposited corresponding to FIG. 3F in the fabrication process.

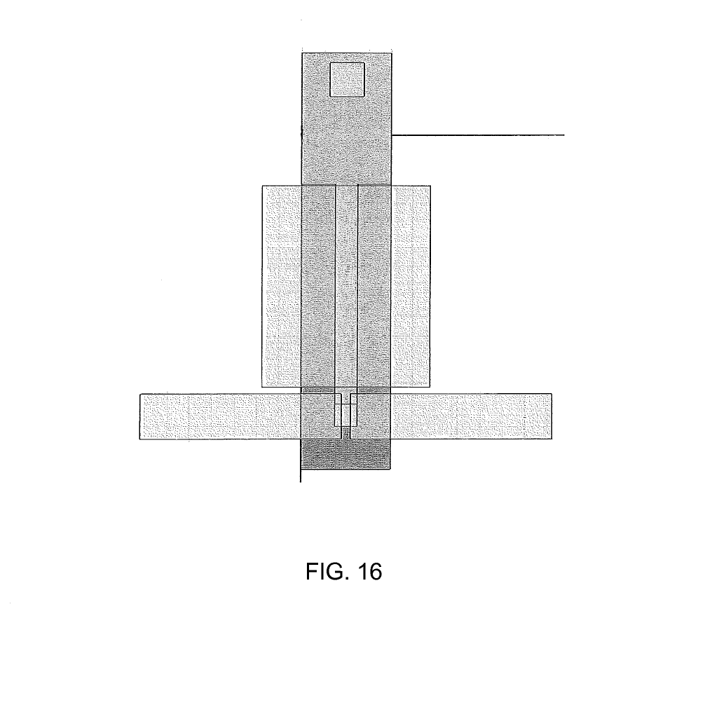

FIG. 16 illustrates a top view of an HFSS drawing of a switch structure.

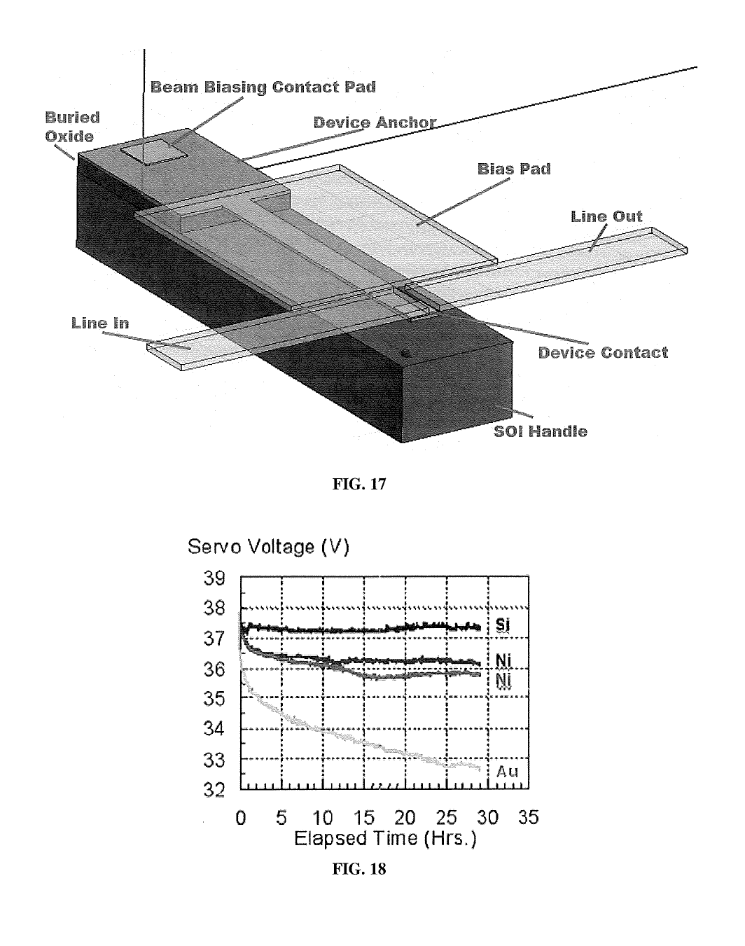

FIG. 17 illustrates a three-dimensional view of a MEMS switch.

FIG. 18 illustrates the long term bias stability versus time for different cantilever materials in air.

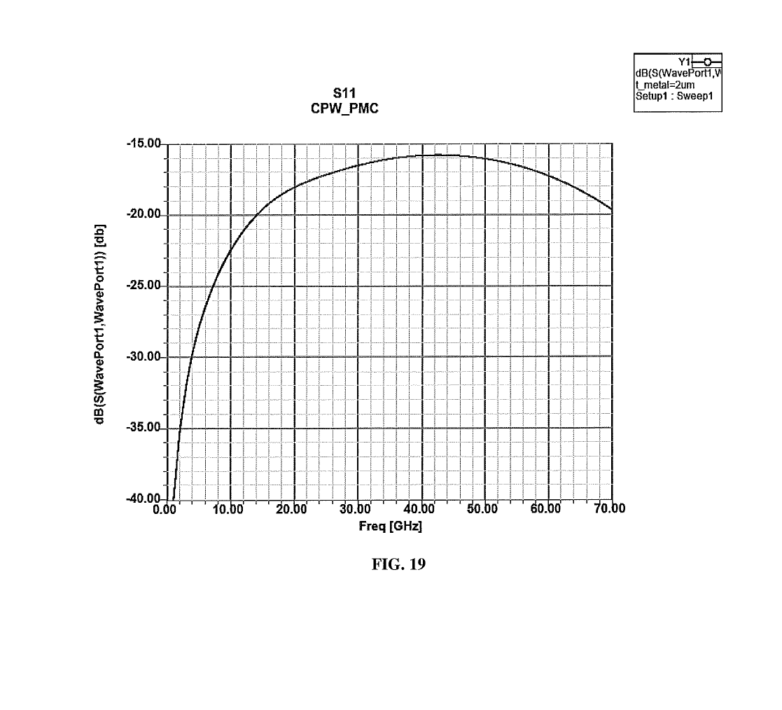

FIG. 19 illustrates a full-wave simulation of switch on-state return loss.

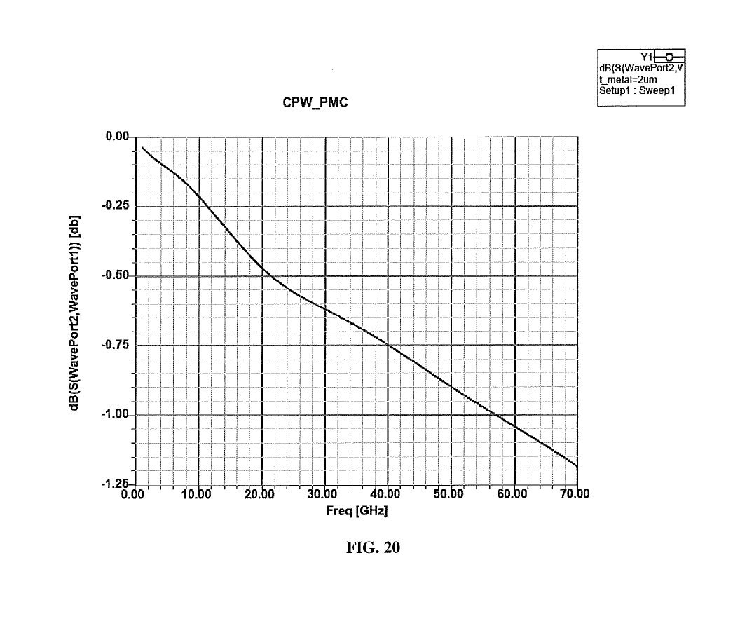

FIG. 20 illustrates a full-wave simulation of switch on-state insertion loss

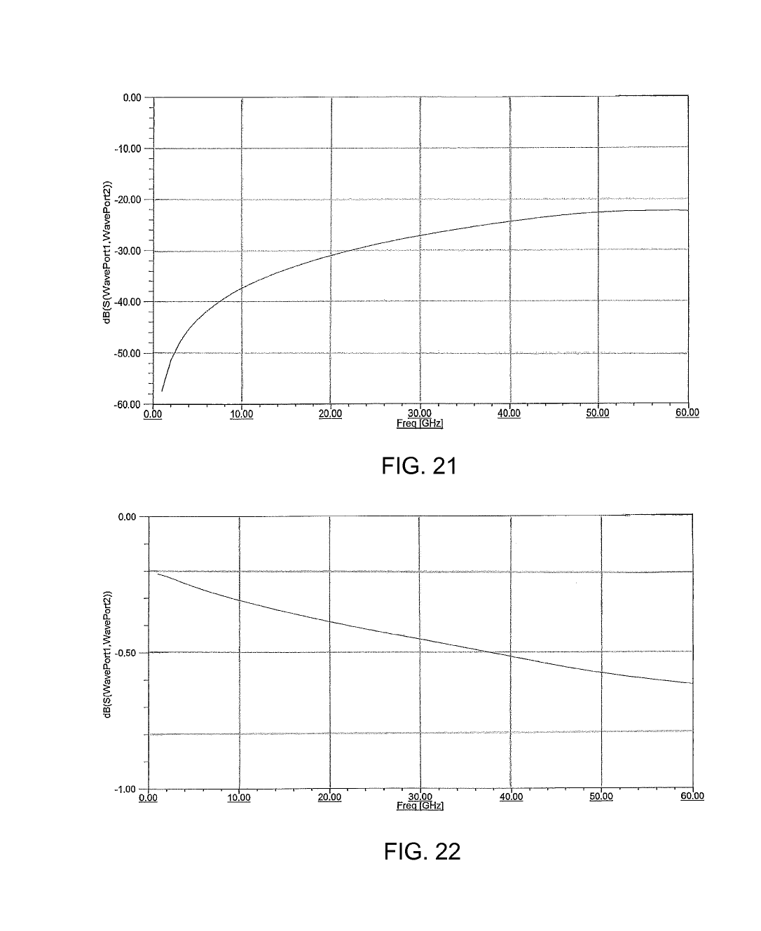

FIG. 21 shows an HFSS simulation plot of return loss from 1 mm switched CPW on SOI.

FIG. 22 shows an HFSS simulation plot of insertion loss from 1 mm switched CPW on SOI.

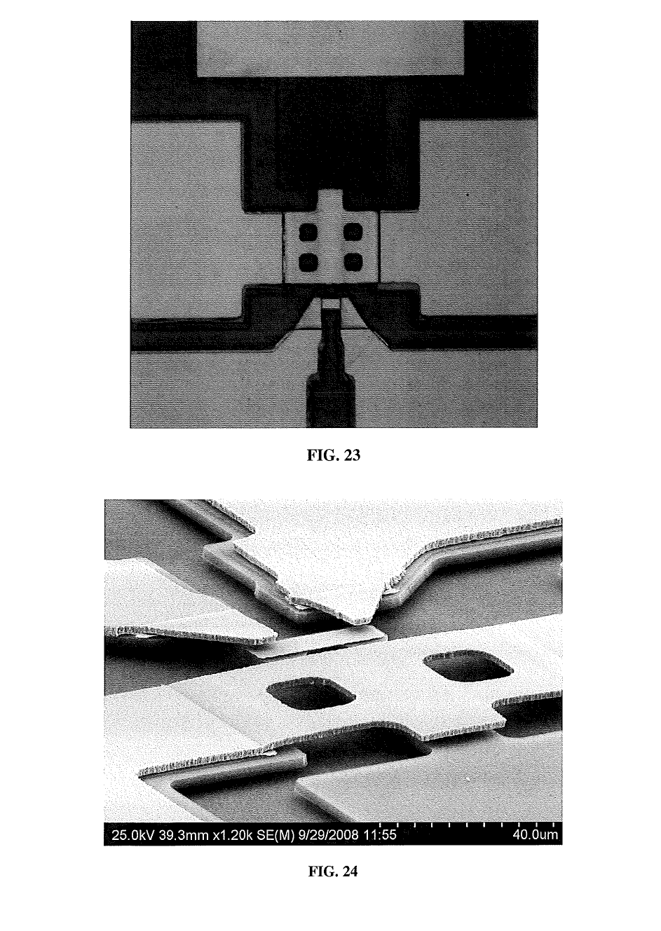

FIG. 23 illustrates a DC ohmic contact switch.

FIG. 24 shows a SEM of DC ohmic contact switch.

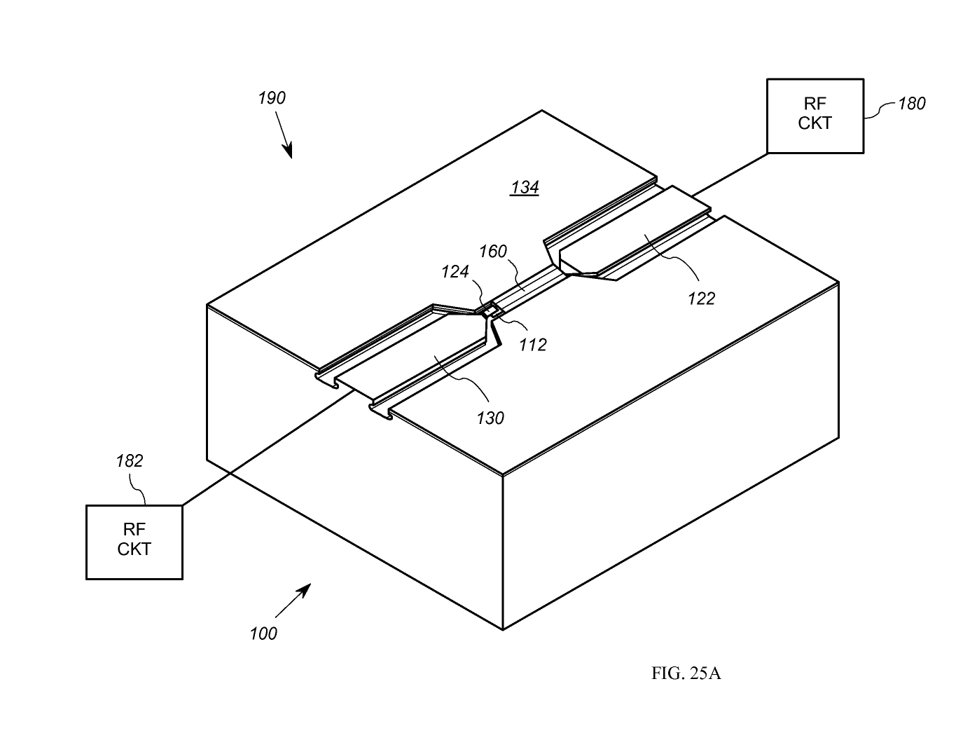

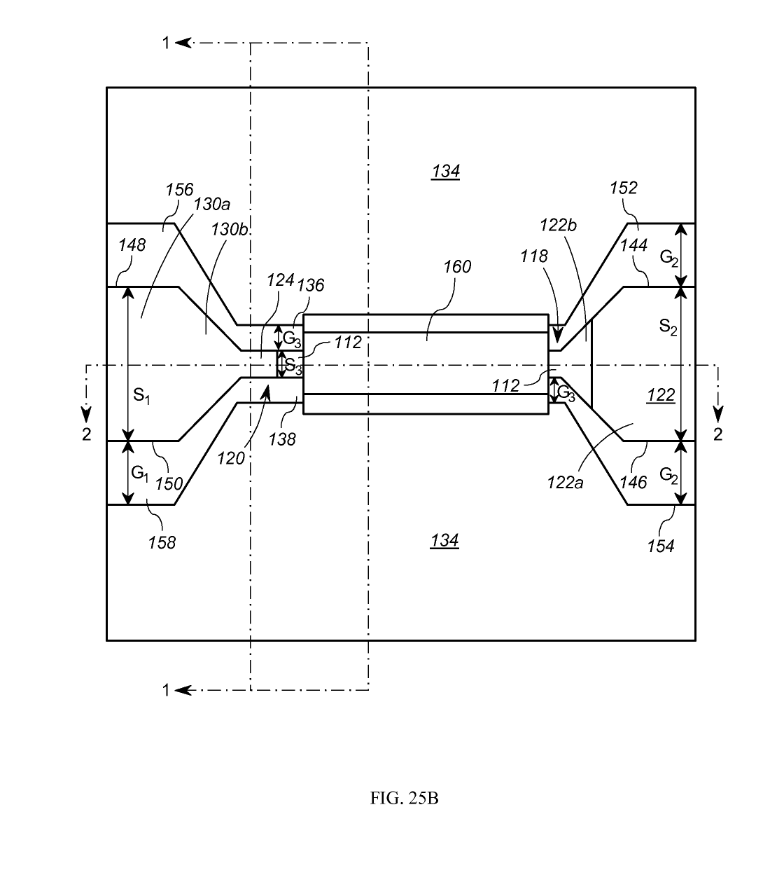

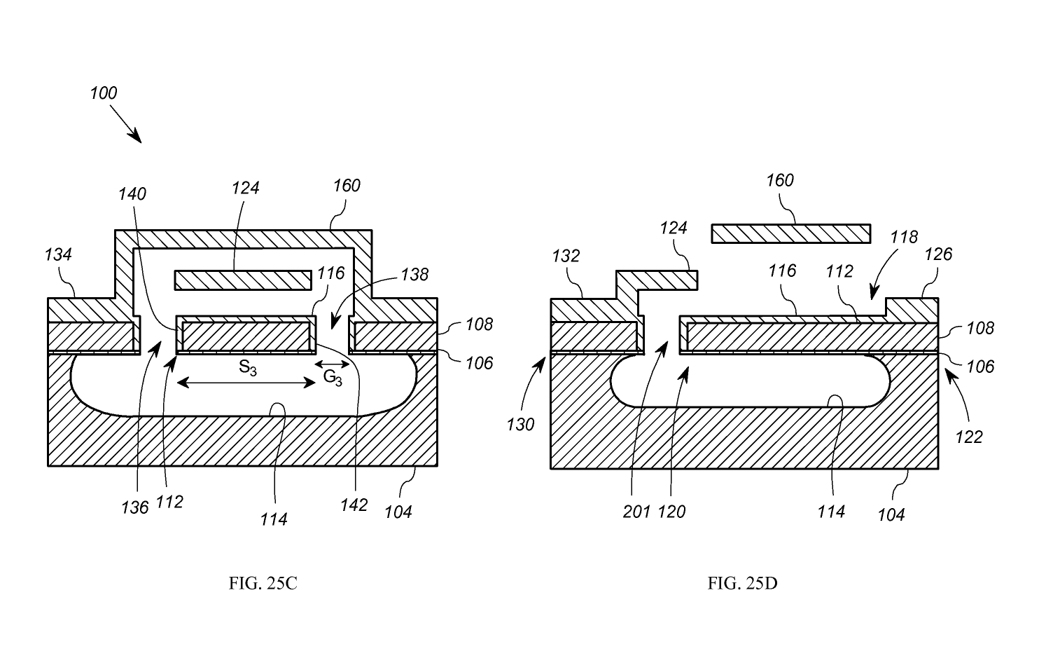

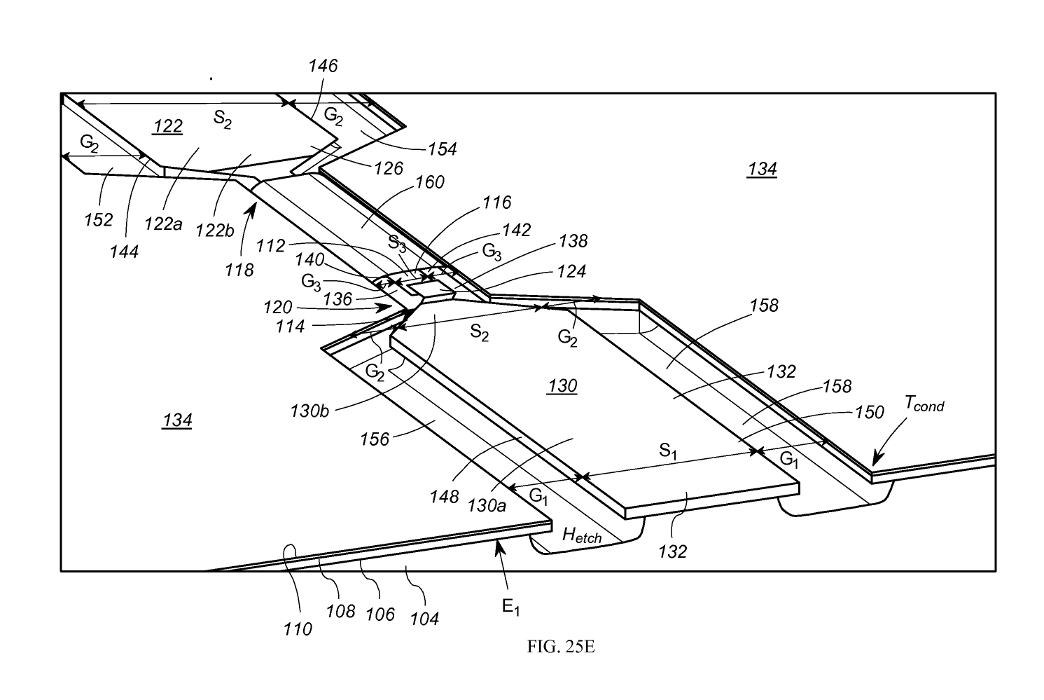

FIGS. 25A-25E show an alternative embodiment of an RF switch 100 that includes additional features and may be fabricated using typical CMOS processes. FIG. 25A shows a perspective view of the RF switch 100, FIG. 25B shows a top plan view of the RF switch 100, FIG. 25C shows a cutaway view taken along line 1-1 of FIG. 25B, and FIG. 25D shows a cutaway view taken along line 2-2 of FIG. 25B. It will be appreciated that FIGS. 25C and 25D are not accurate to scale, but have exaggerated thicknesses to illustrate the various layered structures. It will also be appreciated that FIG. 25A shows the RF switch 100 implemented in a circuit 190 that includes a first RF circuit 180 and a second RF circuit 182. FIG. 25E shows a fragmentary perspective of a portion of the RF switch 100 that represents a magnified version of the device of FIG. 25A.

In general, the RF switch 100 is formed on an SOI semiconductor substrate 102 that includes a handle 104, a buried oxide layer 106 and a device layer 108. The device layer 108 includes a first or top surface 110. As shown in FIGS. 25A and 25B, the top surface 110 of the device layer is largely covered by a conductive ground layer 134 and metallization layers 126 and 132.

The RF switch 100 includes a movable cantilever 112 formed in the device layer 108 which is disposed over a void 114 in the handle 104. The movable cantilever 112 includes a metal portion 116 that forms the conductive portion of the switch 100. The movable cantilever 112 comprises an elongate beam that extends generally over the void 114 in a first direction from a first end 118 to a second end 120. The movable cantilever 112 has at least one width S3 in the direction transverse to the first direction. In this embodiment, the cantilever 112 includes opposing elongate edges 140, 142 that extend from the first end 118 to the second end 120. In this embodiment, the cantilever 122 has substantially the same width S3 along its entire length.

In this embodiment, the width S3 is may suitably be up to ⅓ the width of the transmission line (typically 20 μm) for a cantilever 112 having a length from the first end 118 to the second end 120 of ˜100-300 μμm. In such an embodiment, the thickness of the cantilever 112 may suitably be ˜1-10 μμm. In general, the cantilever 112 may have other dimensions having roughly the same ratio of length to width to height. In any event, the length, width and thickness of the cantilever should be chosen to have a suitably combination of flexibility (to allow movement onto and away from the metal contact 124) and stiffness to ensure mechanical stability and adequate contact and restoring forces. In some cases, the selection of the ratios of length, width and thickness will depend on the material or combination of materials (including the metal portion 116) of the cantilever 112 itself. Such ratios may readily be determined experimentally by testing different combinations for different materials and actuation voltages.

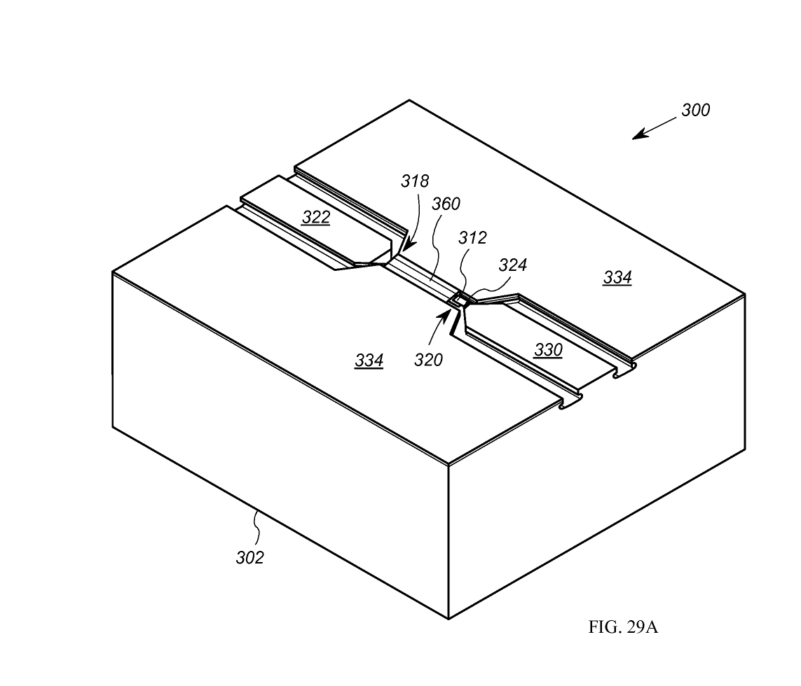

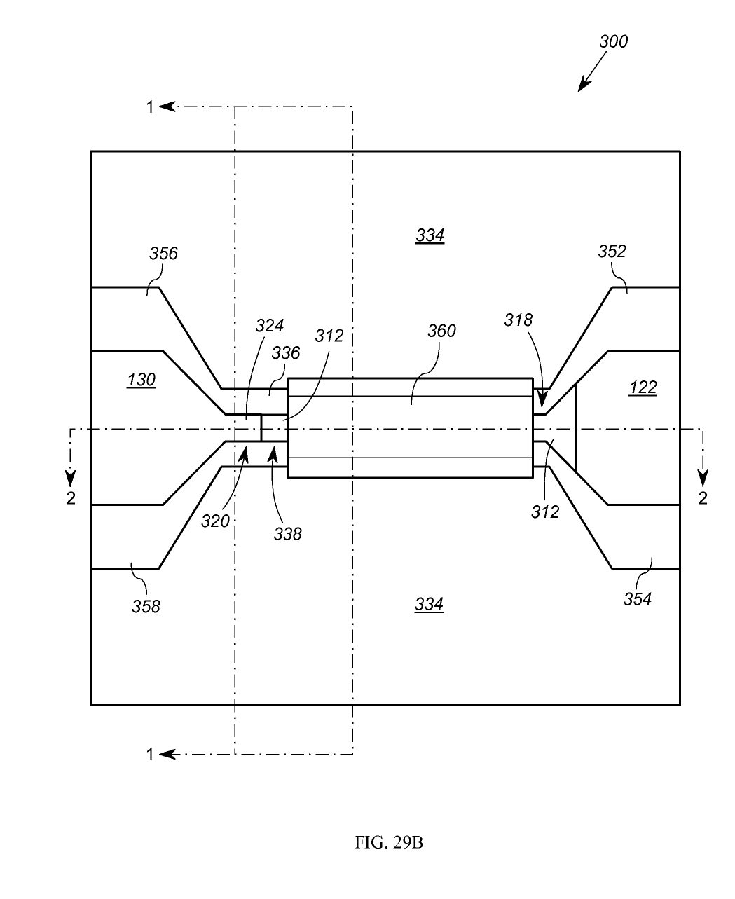

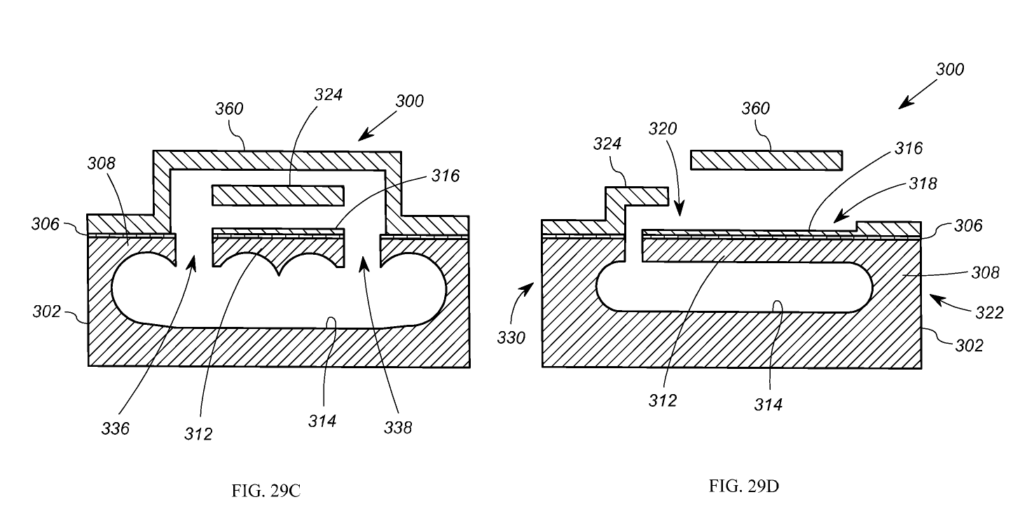

In general, a good aspect ratio range for the cantilever 112 is between 1:1 and 1:3 (height:width), and cannot be equal to or greater than 1:4. Furthermore, an aspect ratio of 2:1 may make the cantilever too stiff. In this embodiment, the height (i.e. thickness) of the aspect ratio should be measured from at the elongate edges 140, 142 with the understanding that the dry release process described herein may cause, in some cases, interior portions of the cantilever 112 located between the elongate edges to actually have a reduced thickness or height. (See, e.g., FIG. 29c, discussed further below).

Referring again to the embodiment of FIGS. 25A-25E, the first end 118 of the cantilever 112 is coupled to an anchor 122, and the second end 120 is disposed over a portion of the void 114, and is adjacent to a metal contact 124. The anchor 122 is formed in the device layer 108, the oxide layer 106 and the handle 104, and includes a metallization layer 126 disposed over the device layer 108. The metallization layer 126 of the anchor 122 has at least one width S1 that is greater than the width S3 to provide a stable cantilever structure. (See FIG. 25E). In this embodiment, the anchor 122 has a first wide portion 122a and a narrowing portion 122b that extends from the first wide portion 122a to an interconnection with the cantilever 112. In general, the anchor 122 has opposing elongate edges 144, 146 that are separated by the width S1 in the first wide portion 122a, and that slowly taper toward each other in the narrowing portion 122b until they intersect with the edges 140, 142, respectively, of the cantilever 112. With this design, the main portion of the anchor 122 can have a wide stable base while having at least some transition region to the narrower cantilever 112.

The metal contact 124 is electrically and mechanically coupled to a contact anchor 130 formed in the device layer 108, the oxide layer 106 and the handle 104. The contact anchor 130 includes a metallization layer 132 disposed over the device layer 108. The metallization layer 132 of the contact anchor 130 has at least one width S2. In the embodiment described herein, the width S2 is roughly equivalent to the width S1, and in any event, is larger than the width S3. In this embodiment, the contact anchor 130 has a first wide portion 130a and a narrowing portion 130b that extends from the first wide portion 130a to the metal contact 124. In general, the contact anchor 130 has opposing elongate edges 148, 150 that are separated by the width S2 in the first wide portion 130a, and that slowly taper toward each other in the narrowing portion 130b until they intersect with the metal contact 124. With this design, the main portion of the contact anchor 130 can have a wide stable base while having at least some transition region to the narrower cantilever 112 for minimizing RF losses.

The RF switch 100 also includes a ground plane 134 formed of a metallization layer on the device layer 108. As will be discussed below, at least portions of the metallization layer 126 of the anchor 122, the metallization layer 132 of the contact anchor 130, and the ground plane 134 are all formed at the same time and are substantially coplanar. The ground plane 134 is disposed adjacent to and on either side of the cantilever 112, the anchor 122 and the contact anchor 130. As shown more clearly in FIGS. 25B and 25E, the ground plane 134 is separated from opposing elongate edges 140, 142 of the cantilever 112 by respective trenches or gaps 136 and 138, each have a similar gap width G3. Similarly, the ground plane 134 is separated from opposing elongate edges 144, 146 of the anchor 122 by respective trenches or gaps 152, 154. Each gap 152, 154 has a gap width G1 in the wide gap portion 122a, and proportionally decreasing gap width in the narrowing gap portion 122b. The ground plane 134 is separated from opposing edges 148, 150 of the contact anchor 130 by respective gaps 156, 158. The gaps 156, 158 have gap widths G2 similar to the gap width G1-. It will be appreciated that the gap widths G1, G2, G3 all define a gap providing suitable isolation between the ground plane 134 and each of the metallizations/metal portions 116, 126 and 132. Furthermore, because the metallizations 116, 126, 132 (in conjunctions with their corresponding gaps) are intended to form an RF waveguide/conductor, the ratio of S1, S2, S3 to the respective gap widths G1, G2, G3 should remain consistent. In other words,

S1/G1=S2/G2=S3/G3

However, it will be appreciated that this ratio may not be appropriate for all embodiments, because of the variations introduced by the etch. In specific embodiments, these values will need to be determined by simulation and may not strictly follow analytic guidelines. Through testing, simulation and/or other evaluation, the values of S1, S2, S3 and the respective gap widths G1, G2, G3 should be chosen such that the ratio of inductance per unit length of the switch 100 and/or cantilever 112 and capacitance per unit length of the switch 100 and/or cantilever 112 ensures no significant impedance mismatch.

In any event, the ratio of the width of the narrowing anchor portion 122b to its corresponding gap width (to the ground plane 134) should be chosen in the same manner. In some devices, it should also remain constant at S1/G1 Likewise, the ratio of the width of the narrowing contact anchor portion 130b to its corresponding gap width (to the ground plane 134) should be chosen in the same manner, and for example remain constant at S1/G1. Thus, in the embodiment described herein, at all points along the signal path from the first RF circuit 180 to the second RF circuit 182 (see FIG. 25A), the ratio of the width of the conductive portions (122, 112, and 130) to the width of the corresponding gaps to the ground plane 134 remains substantially constant. It will be appreciated that the widths S1, S2, S3, G1, G2, G3 can be adjusted to accommodate different desired signal responses.

In any event, the RF switch 100 further includes a biasing metal contact 160 disposed over the movable cantilever 112. The biasing metal contact 160 is electrically disconnected from the metal contact 124 and metal portion 116 of the cantilever 112. The biasing metal contact 160 is physically and electrically connected to the ground plane 134. In the unactuated position, the vertical displacement of the biasing metal contact 160 from the cantilever 112 should exceed the vertical displacement of the metal contact 124 from the cantilever 112.

In the absence of a suitable actuation voltage, the RF switch 100 is biased in a first position, wherein the second end 120 of the cantilever 112 is spaced vertically from the metal contact 124, as shown in FIG. 25D. In operation, when cantilever 112 is subjected to a suitable actuation voltage, it reacts with the biasing metal contact 160 to cause displacement of at least the second end 120 of the cantilever 112 the RF switch 100 is biased in a second position, wherein the second end 120 contacts the metal contact 124, thereby completing a conductive path from the anchor 122 to the contact anchor 130.

In the embodiment described herein where the cantilever 112 is 20 μm wide×260 μm long×5.5 μm thick, a suitable actuation voltage is ˜150V is suitable. Upon receiving the actuation voltage, the second end 120 is displaced into vertically, and into contact with the metal contact 124, thus placing the RF switch 100 in the closed state (second position). The metal portion 116 of the cantilever 112 and the metal contact 124 form the conductive contact. When the RF switch 100 is closed, it forms a transmission line for RF signals from the metallization 126 on the anchor 122, through the metal portion 116 of the cantilever 112, through the metal contact 124, and through the contact anchor 130. In the closed state (second position), the first RF circuit 180 is operably coupled to the second RF circuit 182. In the open state (first position), the first RF circuit 180 is decoupled from the second RF circuit 182.

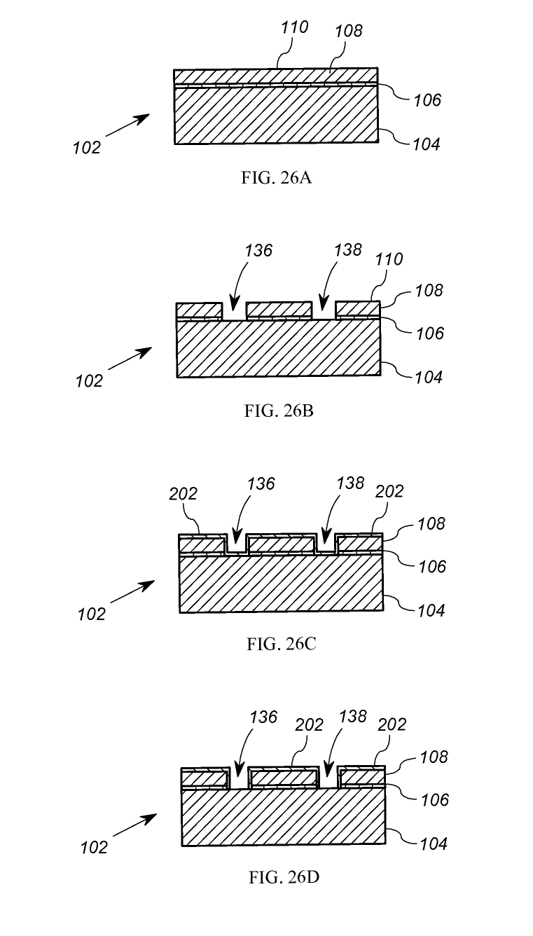

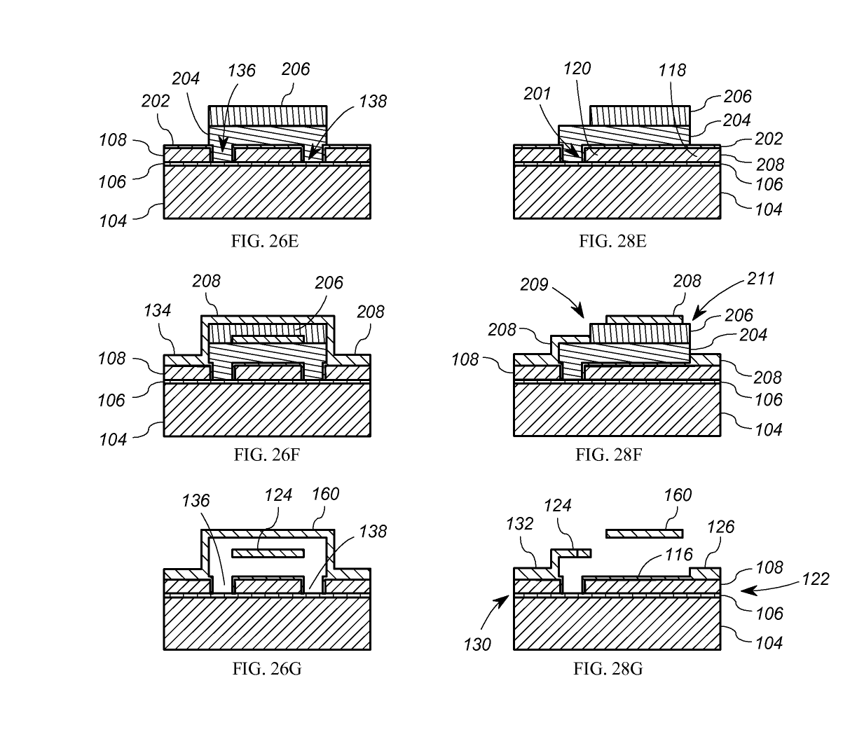

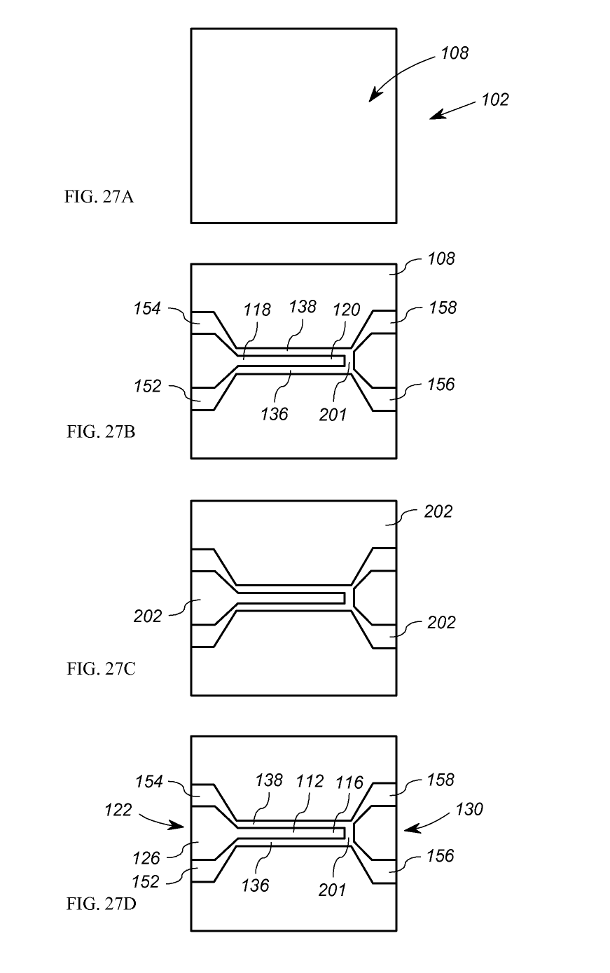

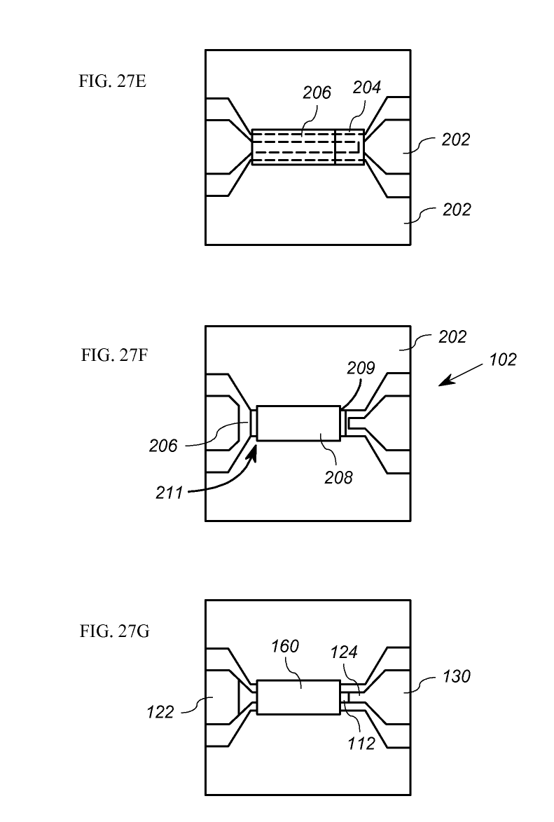

One advantage to the design of the RF switch 100 of FIGS. 25A-25E is that the cantilever 112 can readily be fabricated using a dry etch process to create the void 114. FIGS. 26A-26G and FIGS. 27A-27G illustrate the processing steps used for form the RF switch 100 in this embodiment. FIGS. 26A-26G show cutaway views of the RF switch 100 in various stages of fabrication from a point of view similar to that of FIG. 25C. FIGS. 27A-27G show top plan views of the RF switch in various stages of fabrication corresponding to, respectively FIGS. 26A-26G. FIGS. 28E-28G show cutaway views of the RF switch 100 in various stages of fabrication from a point of view similar to that of FIG. 25D.

The initial starting structure shown in FIGS. 26A and 27A is a typical SOI substrate 102 having the handle 104, the buried oxide layer 106 and the device layer 108. In this embodiment, the device layer 108 has a depth of 5 μm, and the buried oxide layer 106 has a depth of 2 μm.

In a first step, the device outline is formed, specifically, the gaps (i.e. trenches) 136, 138, 152, 154, 156 and 158 are formed, using patterning and reactive ion etching. In addition, a trench 201 is formed that extends between the gap 136 and the gap 138 adjacent the contact anchor 130. The trench 201 defines the free second end 120 of the cantilever 112. The trench 201 may suitably have the same width (transverse of the width of the gaps 136, 138) as that of the gaps 136 and 138 (i.e. G3). The reactive ion etching may be carried out using SF6 plasma, as well as other etching processes using, for example, CF4, Cl2, XeF2, KOH, TMAH, and the like. The gaps 136, 138, 152, 154, 156 and 158 and the trench 201 are formed to the depth of the buried oxide 106 due to the reactive ion etching process. It will be appreciated, however, that depending on the designed-for depth, isotropic or anisotropic etch processes could be used. In any event, the result of this step is shown in FIGS. 26B and 27B.

After forming the device outline, a metallization layer or contact layer 202 is deposited using evaporation or sputtering techniques. The contact layer 202 may be formed of Al, Cu, Ni, Pt, W, Ti or Cr. The result of this step is shown in FIGS. 26C and 27C. The evaporation or sputtering deposition technique is isotropic, such that it results in the deposited contact layer 202 covering the side walls of the gaps 136, 138, 152, 154, 156 and 158, as illustrated in FIG. 27C for the gaps 136 and 138. The contact layer 202 is deposited to a depth of 0.5 μm in this embodiment.

In a following step, the contact layer 202 and the oxide layer are etched out of the bottom (but not the sides) of trenches or gaps 136, 138, 152, 154, 156 and 158. To this end, a wet or vapor phase hydrofluoric acid etch may be employed or a reactive ion etching technique. The result of this step is shown in FIGS. 26D and 27D.

In a next step, two sacrificial layers 204, 206 are formed as shown in FIGS. 26E, 27E and 28E. The sacrificial layer 204, which may suitably be any photoresistis is formed over the cantilever 112 and gaps 136, 138 through their entire length except for a small portion near the anchor 122. The sacrificial layer 204 has a thickness of at least ˜60% of the device layer, which in this embodiment is ˜3 μm. The sacrificial layer 206 is formed in a second photoresist deposition step which could be the same or different resist. It will be appreciated that any suitable layer that is a patternable, conformal, removable layer may be used as the layers 204, 206. The sacrificial layer 206 is formed to completely cover the sacrificial layer 204, except for portion near the contact anchor 130 that is left uncovered. The uncovered portion of the sacrificial layer 204 is above the trench 201 and above the second end 120 of what will eventually be the cantilever 112. The sacrificial layer 204 may suitably be deposited (or formed) using a spin on, spray on, chemical vapor depositiion (CVD), or any other conformal deposition technique. The sacrificial layer 206 may suitably be deposited (or formed) using the same technique.

Thereafter, a thick metallization 208 is deposited over portions of the device (including the sacrificial layers 204, 206) to form the contact 124 and the biasing contact 160 as shown in FIGS. 26F, 27F and 28F. To this end, sputtering or evaporation deposition techniques may be used. From a width perspective as shown in FIG. 26F, the metallization 208 is deposited over both sacrificial layers 204, 206, extending further out over an adjacent portion of the metallization 202 that forms the ground plane 134. From a length perspective shown in FIG. 28F, the metallization 208 extends from at least part of the contact anchor 130 to a point beyond the trench 201, such that a portion of the metallization 208 is disposed vertically above at least a portion of the contact layer 202 on the cantilever 112. The metallization 208 in this embodiment has a brief interruption 209 for a portion of the end of the sacrificial layer 206 that is nearest the second end 120 of the cantilever 112. The metallization 208 resumes for the length beyond the interruption 209 to just short of the opposing end of the sacrificial layer 206. After another interruption 211, the metallization continues after the end of the sacrificial layer 204 to at least a portion of the anchor 122. In order to form the contact 124, the bridge 160, and other thick metal features, another conventional patterning and etch step may be used.

At this point in the process, pre-packaging dicing may occur. The dicing may be partial (e.g. channels are cut for later cleaving) or complete (e.g. individual dies are produced), depending on the implementation.

In any event, the sacrificial layers 204 and 206 are then removed using plasma etching. The result of this process is shown in FIGS. 26G, 27G and 28G. At this point, the contact 124, the biasing contact 160, the anchor 122 and the contact anchor 130 are fully formed. However, the cantilever 112 is still solidly and fully connected to the substrate 102 along its entire length.

To release the cantilever 112, the silicon is dry etched using an XeF2 etching process. The resulting RF switch 100 is shown in FIGS. 25A-25E, discussed further above. The dry etch process is isotropic, and therefore etches in every direction where the silicon of the handle 104 is accessible. The etch removes in every direction to a predetermined depth, but does not etch any silicon covered by a metallization. The depth of the etch is chosen so as to release the cantilever 112 completely as shown in FIGS. 25C and 25D without releasing or disconnecting the anchor 122 or the contact anchor 130. In particular, it will be appreciated that the handle 104 under the anchor 122 and contact anchor 130 will also be etched away. However, because S1 and S2 are greater than S3, the etching process does not separate the anchor 122 and the contact anchor 130 from the handle 104.

The dry etch process used to release the cantilever 112 is conducive to standard CMOS manufacturing techniques. Accordingly, the RF device 100 and its method of fabrication are strongly advantageous for integration into substrates in which electrical CMOS circuits are fabricated. One advantage is that the dry release process facilitates the use of normally available contact metals such as Al, Cu, Ni, Pt, W, Ti and Cr, which otherwise would not necessarily withstand known wet release techniques well. With reference to FIG. 25A, it will be appreciated that the RF switch 100 may be formed on the same substrate as either or both of the RF circuits 180, 182.

A similar process may be employed in an RF switch fabricated in a non-SOI substrate. FIGS. 29A-29E show an alternative embodiment of the RF switch of FIGS. 25A-25E that is formed with bulk silicon instead of an SOI substrate. FIG. 29A shows a perspective view of the RF switch 300, FIG. 29B shows a top plan view of the RF switch 300, FIG. 29C shows a cutaway view taken along line 1-1 of FIG. 29B, and FIG. 29D shows a cutaway view taken along line 2-2 of FIG. 29B. It will be appreciated that FIGS. 29C and 29D are not accurate to scale, but have exaggerated thicknesses to illustrate the various layered structures. FIG. 29E shows a fragmentary perspective of the portion of the RF switch 300 that represents a magnified version of the device of FIG. 29A.

In general, the RF switch 300 is formed on a bulk semiconductor substrate 302 that includes a first or top surface 310. As shown in FIGS. 29A and 29B, the top surface 310 of the substrate 302 is largely covered by a conductive ground layer 334 and associated metallization layers 326 and 332. A dielectric layer 306 is disposed between the various metallization portions 336, 332, 334 and the top surface 310 of the substrate 302.

The RF switch 300 includes a movable cantilever 312 formed in a device portion 308 of the substrate 302 which is disposed over a void 314 in the semiconductor substrate 302. The movable cantilever 312 includes a metal portion 316 that forms the conductive portion of the switch 300. The movable cantilever 312 comprises an elongate beam that extends generally over the void 314 in a first direction from a first end 318 to a second end 320. In this embodiment, the cantilever 312 includes opposing elongate edges 340, 342 that extend from the first end 318 to the second end 320. In this embodiment, the cantilever 312 has substantially the same shape and dimensions as the cantilever 112 of FIGS. 25A-25E. In any event, the length, width and thickness of the cantilever 312 should be chosen to have a suitably combination of flexibility (to allow movement onto and away from the metal contact 324) and stiffness to ensure mechanical stability and flexibility. In some cases, the selection of the ratios of length, width and thickness will depend on the material or combination of materials (including the metal portion 316) of the cantilever 312 itself. Such ratios may readily be determined experimentally by testing different combinations for different materials and actuation voltages.

In any event, the first end 318 is coupled to an anchor 322, and the second end 320 is disposed over a portion of the void 314, and is adjacent to a metal contact 324. The anchor 322 is formed in the substrate 302, and includes the metallization layer 326 and a part of the dielectric layer 306. The anchor 322 and its component elements have substantially the same shape and dimensions as the anchor 122 of FIGS. 25A-25E.

The metal contact 324 is electrically and mechanically coupled to a contact anchor 330 formed in the semiconductor substrate 302. The contact anchor 330 includes a metallization layer 332 disposed over the substrate 302, and includes a portion of the dielectric layer 306. The contact anchor 330 and its component elements have substantially the same shape and dimensions as the anchor 130 of FIGS. 25A-25E.

The RF switch 300 also includes the ground plane 334 formed of a metallization layer on the dielectric layer 306, which in turn is disposed on the surface 310 of the substrate 302. As will be discussed below, portions of the metallization layer 326 of the anchor 322, the metallization layer 332 of the contact anchor 330, and the ground plane 334 are all formed at the same time. The ground plane 334 is disposed adjacent to and on either side of the cantilever 312, the anchor 322 and the contact anchor 330. As shown more clearly in FIG. 29B and 29E, the ground plane 334 is separated from opposing elongate edges 340, 342 of the cantilever 312 by respective gaps 336, 338 that are substantially identical to gaps 136, 138 of FIGS. 25A-25E. Similarly, the ground plane 334 is separated from opposing elongate edges of the anchor 122 by gaps 352, 354 that are substantially identical to gaps 152, 154 of FIGS. 25A-25E. The ground plane 334 is separated from opposing edges of the contact anchor 330 by respective gaps 356, 358 that are substantially identical to the gaps 156, 158 of FIGS. 25A-25E.

The RF switch 300 further includes a biasing metal contact 360 disposed over the movable cantilever 312. The biasing metal contact 360 is electrically disconnected from the metal contact 324 and metal portion 316 of the cantilever 312. The biasing metal contact 360 is physically and electrically connected to the ground plane 334. In the unactuated position, the vertical displacement of the biasing metal contact 360 from the cantilever 312 should exceed the vertical displacement of the metal contact 324 from the cantilever 312.

The operation of the RF switch 300 is substantially identical to that of the RF switch 300. The fabrication of the RF switch 300 may suitably be carried out in a manner that is substantially identical to that of RF switch 100. However, in contrast to the RF switch 100, the fabrication process of the RF switch 300 further includes a step of introducing the dielectric layer 306 onto the substrate top surface 310.

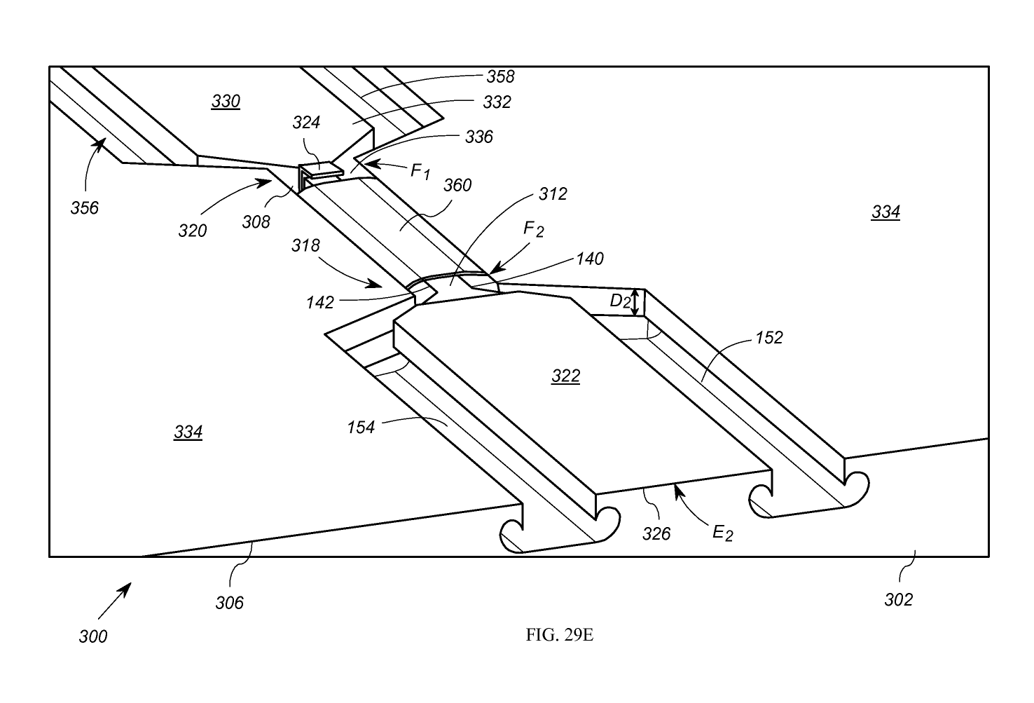

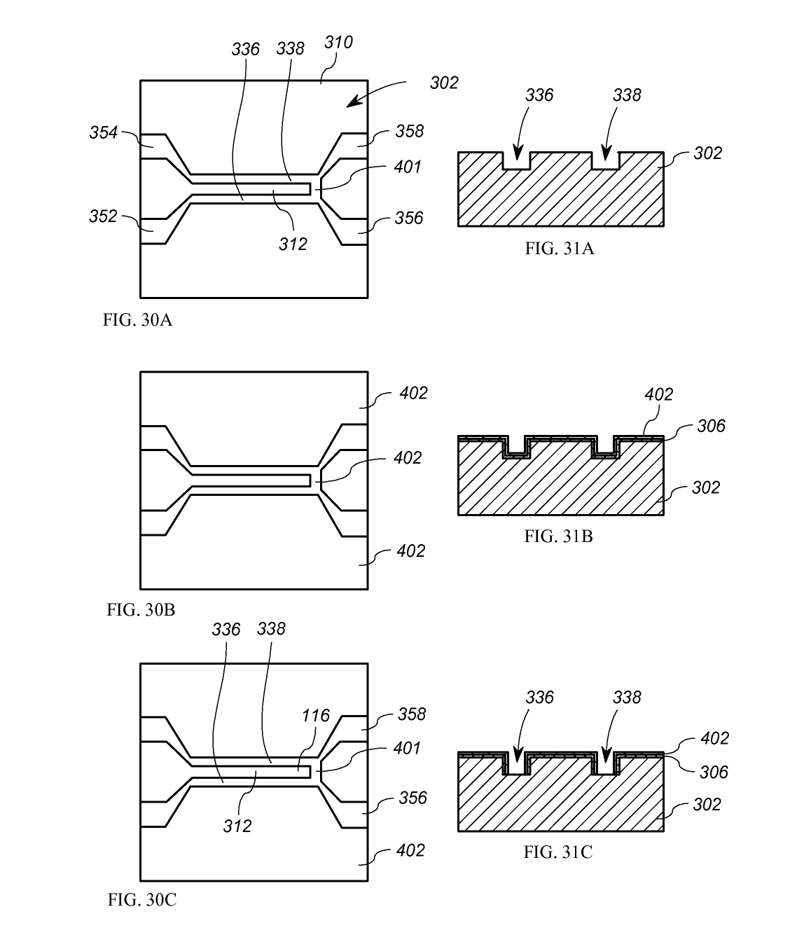

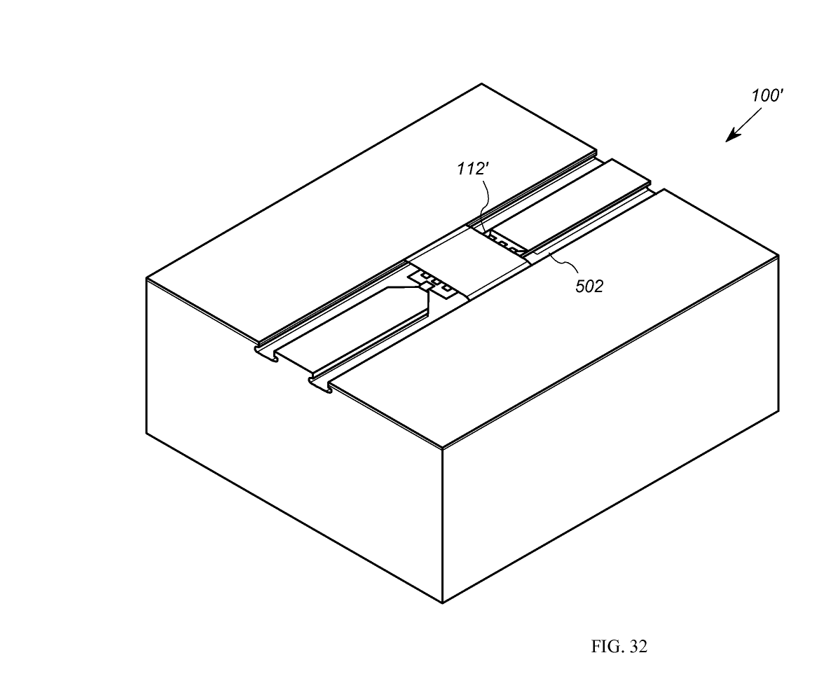

In particular, the fabrication of the RF switch 300 begins with forming the device outline on a bulk silicon substrate 302. Specifically, the gaps (i.e. trenches) 336, 338, 352, 354, 356 and 358 are formed, using patterning and reactive ion etching. In addition, a trench 401 similar to the trench 201 is formed that extends between the gap 336 and the gap 338 adjacent the contact anchor 330. This trench 401 defines the free second end 320 of the cantilever 312. The reactive ion etching may be carried out using SF6 plasma. As discussed above, other processes may be used. The gaps 336, 338, 352, 354, 356 and 358 and the trench are formed to balance the design tradeoff between switch gap, metal thickness, and aspect ratio. For example, a good aspect ratio range for the cantilever 312 (and 112) is between 1:1 and 1:3 (height:width), and cannot be equal to or greater than 1:4. An aspect ratio of 2:1 may make the cantilever too stiff. In one embodiment, for example, the trench depth would be 5 μm, the contact metal would be 0.5 μm, and a good beam width would be 15 μm and a good gap between the contact point and the movable beam 312 would be 1 μm. The result of this step is shown in FIGS. 30A and 31A.

After forming the device outline, both the dielectric layer 306 and a metallization layer or contact layer 402 are formed on the surface 310. The dielectric layer 306 may be grown or deposited using, for example, thermal growth, sputtering, evaporation, CVD, spin on, spray on, etc. techniques. The contact layer 402 is deposited using evaporation or sputtering techniques. The metallization contact layer 402 may be formed of Al, Cu, Ni, Pt, W, Ti or Cr. In this embodiment, the dielectric layer 306 has a thickness of, depending on the dielectric, between 100 nm-1 μm. The contact layer 402 has a thickness or depth of 300 nm-1 μm.

In a following step, the contact layer 402 and the dielectric layer 306 are etched out of the bottom (but not the sides) of trenches or gaps 336, 338, 352, 354, 356, 358 and 401. The result of this step is shown in FIGS. 30C and 31C. Thereafter, the process is substantially similar to that described above in connection with FIGS. 26E-26G, 27E-27G and 27E-27G.

In another embodiment, it is possible to maintain the constant transmission line width through the body of the switch. This embodiment is shown in FIG. 32. FIG. 32 shows a perspective view of a switch 100′ incorporating a constant transmission line width. In FIG. 32, the switch 100′ is configured in a similar manner as the switch 100 of FIGS. 25A-25E, except that the width of the movable cantilever 112′ is effectively the same width as that of the anchor 122 and the contact anchor 130. In this case, the flexibility of the beam 112′ is imparted by perforations or through holes 502 in the cantilever 112′. Otherwise, the overall structure may be the same as that of the switch 100.

In another variant, the cantilever 112 of the switch 100 may be replaced by a beam that is fixed on both ends, forming a diaphragm. Such diaphragm would be fixed to anchors located at the positions of the anchor 122 and the contact anchor 130 of FIG. 25A. In such a case, the switch beam would be actuated to electrically couple to a contact that is vertically displaced from the middle of the beam. Such a design, as well as other suitable MEMs geometries, can benefit from the dry release methods discussed above.

It will be appreciated that the above-described embodiments are merely illustrative, and that those of ordinary skill in the art may readily devise their own implementations and modifications that incorporate the principles of the present invention and fall within the spirit and scope thereof.

While the invention has been illustrated and described in detail in the drawings and foregoing description, the same is to be considered as illustrative and not restrictive in character, it being understood that only preferred embodiments have been shown and described and that all changes and modifications that come within the spirit of the invention are desired to be protected.

What is claimed is:

1. A MEMS switch, comprising:
a semiconductor substrate including a device layer and a handle;
a movable cantilever formed in the semiconductor substrate, the cantilever disposed over a void in the handle;
a cantilever anchor formed in the semiconductor substrate and defining a side wall of the void;
a metal portion formed on at least a portion of the movable cantilever;
a metal contact formed proximate an end of the movable cantilever; and
a biasing metal contact formed adjacent the cantilever, the biasing metal contact electrically disconnected from the metal contact.

2. The MEMS switch of claim 1, wherein the void defines a chamber including a bottom wall and sidewalls formed in the handle.

3. The MEMS switch of claim 1, further comprising an oxide layer between the device layer and the box.

4. The MEMS switch of claim 3, wherein the void is formed in the handle substrate below a level of the buried oxide layer.

5. The MEMS switch of claim 4, wherein a first part of the metal contact is disposed on the device layer.

6. The MEMS switch of claim 1, including at least one dielectric layer formed in the movable cantilever.

7. The MEMS switch of claim 6, wherein a first part of the metal contact is disposed on the dielectric layer disposed on the device layer.

8. A MEMS switch, comprising:
a semiconductor substrate having a first surface;
a movable cantilever formed in the semiconductor substrate, the cantilever disposed over a void in the semiconductor substrate;
a metal portion formed on at least a portion of the movable cantilever;
a metal contact disposed proximate an end of the movable cantilever; and
a biasing metal contact disposed over the movable cantilever, the biasing metal contact electrically disconnected from the metal contact; and
wherein the movable cantilever is movable between a first position defining a first RF connectivity between the metal contact and the metal portion, and a second position defining a second RF connectivity between the metal contact and the metal portion, wherein the first RF connectivity is different from the second RF connectivity.

9. The MEMS switch of claim 8, wherein the movable cantilever includes a first end affixed to an anchor, and a second end opposite from the first end, and wherein the metal portion extends in a first direction from the first end to the second end.

10. The MEMS switch of claim 9, wherein the metal contact is disposed adjacent the first end of the movable cantilever, and is displaced from the first end in a second direction perpendicular to the first direction.

11. The MEMS switch of claim 10, wherein the biasing metal contact is disposed adjacent to a portion of the movable cantilever between the first end and the second end.

12. The MEMS switch of claim 9, wherein the cantilever has a first width W1 defined in a direction normal to the first direction, and the anchor has at least a second width W2 defined in the direction normal to the first direction, and wherein W2>W1.

13. The MEMS switch of claim 9, wherein:
the biasing metal contact is electrically coupled to a conductive layer on the semiconductor substrate;
a first elongate edge of the movable cantilever extending in the first direction is displaced from the conductive layer by a first gap and a second elongate edge of the movable cantilever extending in the first direction is displaced from the conductive layer by a second gap.

14. The MEMS switch of claim 11, wherein:
the anchor has a first edge extending in the first direction that is displaced from the conductive layer by a third gap and a second edge extending in the first direction that is displaced from the conductive layer by a fourth gap;
the first gap has a first gap width G1 and the second gap has the first gap width G1;
the third gap has a second gap width G2 and the fourth gap has the second gap width G2, wherein G1 differs from G2.

15. The MEMS switch of claim 8, wherein the movable cantilever comprises a first layer of the semiconductor substrate disposed on a buried oxide layer, and wherein the metal portion is disposed on the first layer of the semiconductor substrate.

16. The MEMS switch of claim 8, wherein the movable cantilever comprises a first layer of the semiconductor substrate, and wherein the at least one dielectric layer is disposed on the first layer of the semiconductor substrate, and the metal portion is disposed on the at least one dielectric layer.

17. A method of fabricating a switch, comprising:
a) forming adjacent trenches in a semiconductor substrate, defining an elongate portion of the semiconductor substrate between the adjacent trenches;
b) forming a connecting trench between the adjacent trenches, the connecting trench defining a switching end of the elongate portion
c) forming a metal layer over a first surface of the semiconductor substrate and on sides of the adjacent trenches;
d) forming a metal contact extending adjacent the switching end of the elongate portion.
e) removing portions of the semiconductor substrate below the elongate portions via the adjacent trenches to form a void below the elongate portion, the void extending between the adjacent trenches.

18. The method of claim 14, wherein step a) further comprises forming the adjacent trenches to a depth of a buried oxide layer in the semiconductor substrate.

19. The method of claim 15, wherein step e) further comprises removing portions of the semiconductor substrate below the buried oxide layer to from the void.

20. The method of claim 14, wherein step c) further comprises:
i) forming a dielectric layer on the first surface of the semiconductor substrate; and
ii) forming the metal layer on the dielectric layer.

21. The method of claim 16, wherein step e) further comprises dry-etching the semiconductor substrate below the elongate portion via the adjacent trenches.

22. The method of claim 18, wherein step d) further comprises:
i) forming a first sacrificial layer within said adjacent trenches and on at least a portion of the elongate portion;
ii) forming the metal contact on at least a portion of the first sacrificial layer; and
iii) removing the first sacrificial layer.

23. The method of claim 19, further comprising forming a metal biasing contact, electrically disconnected from the metal contact, over a portion of the adjacent trenches and the elongate portion.
